(19) United States
(12) Patent Application Publication
(10) Pub. No.: US 2025/0324742 A1
(43) Pub. Date: Oct. 16, 2025

(54) STACKED FIELD EFFECT TRANSISTOR INTEGRATED WITH VERTICAL DIODE

(71) Applicant: International Business Machines Corporation, Armonk, NY (US)

(72) Inventors: Chen Zhang, Santa Clara, CA (US); Ruilong Xie, Niskayuna, NY (US); HUIMEI ZHOU, Albany, NY (US); Anthony I-Chih Chou, Guilderland, NY (US)

(21) Appl. No.: 18/634,950

(22) Filed: Apr. 14, 2024

(51) Int. Cl. H01L 27/06; H01L 21/822; H01L 21/8238; H01L 23/528; H01L 27/092; H01L 29/06; H01L 29/423; H01L 29/66; H01L 29/775

(52) U.S. Cl. CPC H10D 84/811; H01L 23/5286; H10D 30/014; H10D 30/43; H10D 30/6735; H10D 62/121; H10D 84/0186; H10D 84/038; H10D 84/856; H10D 88/01

(57) ABSTRACT

A semiconductor structure has a logic region and a passive region. The logic region includes a vertically stacked top and bottom transistors in which the top transistor has a topmost channel, and the bottom transistor has a bottommost channel. The passive region includes a semiconductor mesa having a top surface co-planar or above a topmost channel of the top transistor and a bottom surface co-planar or below the bottommost channel of the bottom transistor.

### BACKGROUND

The present invention relates generally to the electrical, electronic and computer arts and, more particularly, to techniques for integrating stacked field effect transistors (FETs) and passive devices and the like in a semiconductor device.

Buried power rails (BPR) and backside power distribution networks (BSPDN) are very attractive schemes for future complementary metal oxide semiconductor (CMOS) scaling. However, with continued scaling, a problem has arisen with regard to integrating backside structures with stacked FETs and passive devices.

### BRIEF SUMMARY

Principles of the invention provide techniques for integrating a stacked FET with a passive device. In one aspect, an exemplary semiconductor structure includes a stacked transistor having a top transistor over a bottom transistor and a gate structure and a passive device positioned laterally to the stacked transistor and having a passive device top surface and a passive device bottom surface. The top transistor has a first source-drain connected to a second source drain by a topmost channel. The bottom transistor has a third source-drain connected to a fourth source drain by a bottommost channel. The gate structure surrounds the topmost channel and the bottommost channel. The passive device top surface is co-planar or above (i.e., no lower than) a top surface of the topmost channel. The passive device bottom surface is co-planar or below (i.e., no higher than) a gate structure bottom surface.

In another aspect, another exemplary semiconductor structure includes a stacked transistor having a top transistor, over a bottom transistor, and a gate structure 141. And includes a passive device positioned laterally to the stacked transistor and having a passive device top surface, a passive device bottom surface and a plurality of passive device sidewalls. And further includes a protection liner on the passive device and a shallow trench isolation under the protection liner laterally surrounding the passive device. At least one of the passive device sidewalls contacts the protection liner and contacts the shallow trench isolation.

In a further aspect, an exemplary semiconductor structure includes a logic region and a passive region. The logic region includes a vertically stacked top and bottom transistors in which the top transistor has a topmost channel and the bottom transistor has a bottommost channel. The passive region includes a semiconductor mesa having a top surface co-planar or above a topmost channel of the top transistor and a bottom surface co-planar or below the bottommost channel of the bottom transistor.

In yet a further aspect, an exemplary semiconductor structure includes a substrate having a substrate frontside and a substrate backside, a transistor region on the substrate frontside, a passive region including a semiconductor mesa having a mesa top surface and a mesa bottom surface. The transistor region including a vertically stacked field effect transistor including a top transistor over a bottom transistor in which the top transistor includes a topmost channel and the bottom transistor includes a bottommost channel. The transistor region also includes a gate structure surrounding the topmost channel and the bottommost channel. The mesa top surface co-planar or above a top surface of the topmost channel and the mesa bottom surface co-planar or below a bottom surface of the bottommost channel. A backside contact contacts the mesa bottom surface.

In still a further aspect, an exemplary method of forming a semiconductor structure includes providing a semiconductor substrate, forming a multilayer stack of channel material and sacrificial material, removing the multilayer stack from a passive region of the substrate, growing a semiconductor in the passive region, doping the semiconductor to form a top passive region having a first polarity and lower passive region having a second polarity wherein the first polarity is opposite of the second polarity, etching the multilayer stack and the semiconductor to form a multilayer stack fin and a semiconductor mesa wherein the semiconductor mesa has a top mesa surface and a bottom mesa surface, forming a protection liner on the semiconductor mesa, and forming a transistor region from the multilayer stack fin in which the transistor region comprises a top transistor over a bottom transistor. The top transistor includes a topmost channel and the bottom transistor includes a bottommost channel and in which the top mesa surface is co-planar or above the topmost channel and the bottom mesa surface is co-planar or below the bottommost channel.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
Allow further competitive scaling of stacked FETs by successfully integrating stacked FETs, backside power distribution networks (BSPDN) and passive devices.
Forming high quality junction within a grown semiconductor mesa, which has lower defects than a merged source/drain formed junctions, provides diodes with more ideal behavior.
A semiconductor mesa diode having a round shape (when viewed top-down) can maximize area to periphery ratio which improves ideality of the diode as sidewalls of semiconductor structures usually have defects.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 depicts a cross-section of a semiconductor structure having a stacked transistor region and a passive region in accordance with an aspect of the invention;

FIG. 2 lists exemplary process steps to manufacture the structure of FIG. 1 in accordance with an aspect of the invention; and

FIGS. 3-11 depict cross-sections of a semiconductor structure having a transistor region and a passive region during various steps of FIG. 2 in accordance with an aspect of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

In an aspect of the invention, and referring to the figures discussed in detail below, an exemplary semiconductor structure includes a stacked transistor having a top transistor 140 over a bottom transistor 240 and a gate structure 141, and a passive device positioned laterally to the stacked transistor and having a passive device top surface and a passive device bottom surface. The top transistor comprises a first source/drain 144 connected to a second source drain 145 by a topmost channel 102T. The bottom transistor comprises a third source/drain 244 connected to a fourth source/drain 245 by a bottommost channel 102B. The gate structure 141 surrounds the topmost channel 102T and the bottommost channel 102B. The passive device top surface is co-planar or above a top surface 102TS of the topmost channel of the channel material 102. The passive device bottom surface is co-planar or below a gate structure bottom surface 141BS.

Optionally, a passive device height is greater than a height from the gate structure bottom surface 141BS to the top surface 102TS of the top channel 102T.

In a further option, a passive device height is from 100 nm to 160 nm.

In another option, the height from the gate structure bottom surface 141BS to the top surface of the topmost channel is from 50 nm to 110 nm.

In yet another option, a ratio of the passive device height to the height from the gate structure bottom surface 141BS to the top surface 102TS of the topmost channel of the channel material 102 is equal to or greater than 1.4.

In another aspect, an exemplary semiconductor structure includes a stacked transistor having a top transistor 140 over a bottom transistor 240 and a gate structure 141, a passive device positioned laterally to the stacked transistor and having a passive device top surface, a passive device bottom surface and a plurality of passive device sidewalls, a protection liner 124 on the passive device, and a shallow trench isolation 130 under the protection liner laterally surrounding the passive device. At least one of the passive device sidewalls contacts the protection liner 124 and contacts the shallow trench isolation 130.

Optionally, a length of the at least one of the passive device sidewalls contacting the shallow trench isolation 130 is equal to or less than 50 nm.

Optionally, the semiconductor structure further includes a frontside contact 150 contacting the passive device top surface, and a backside contact 160 contacting the passive device bottom surface.

In a further aspect, an exemplary semiconductor structure includes a logic region comprising vertically stacked top and bottom transistors wherein the top transistor 140 includes a topmost channel 102T and the bottom transistor 240 includes a bottommost channel 102B, and a passive region 120 comprising a semiconductor mesa 220 having a top surface co-planar or above a topmost channel 102T of the top transistor 140 and a bottom surface co-planar or below the bottommost channel 102B of the bottom transistor 240.

Optionally, the semiconductor mesa 220 includes a vertical diode.

Optionally, the semiconductor structure 10 of claim 9, further comprising a frontside contact 150 and a backside contact 160 each connected to the semiconductor mesa 220.

Optionally, the semiconductor mesa 220 is round when viewed in plan view.

In still a further aspect, an exemplary semiconductor structure includes a substrate 101 having a substrate frontside 111 and a substrate backside 112, a transistor region on the substrate frontside in which the transistor region includes a vertically stacked field effect transistor having a top transistor 140 over a bottom transistor 246 in which the top transistor includes a topmost channel 102T and the bottom transistor includes a bottommost channel, a gate structure 141 surrounding the topmost channel and the bottommost channel, a passive region 120 including a semiconductor mesa 220 having a mesa top surface co-planar or above a top surface of the topmost channel 102T and a mesa bottom surface co-planar or below a bottom surface of the bottommost channel 102B, and a backside contact 160 contacting the mesa bottom surface.

Optionally, the semiconductor mesa 220 includes a vertical diode.

Optionally, the semiconductor mesa 220 is round when viewed in plan view.

Optionally, a semiconductor mesa height 168 is greater than a height from the substrate backside 101BS to the top surface 102TS of the topmost channel 102T.

Optionally, a semiconductor mesa height 168 is greater than a height from a gate structure bottom surface 141BS to the top surface 102TS of the topmost channel 102T.

Optionally, the semiconductor mesa height 168 is from 100 nm to 160 nm.

Optionally, the height from the gate structure bottom surface 141BS to the top surface 102TS of the topmost channel 102T is from 50 nm to 110 nm.

Optionally, a ratio of the mesa height 168 to the height from the gate structure bottom surface 141BS to the top surface 10TS of the topmost channel of the channel material 102 is equal to or greater than 1.4.

Optionally, the semiconductor structure further includes a plurality of mesa sidewalls in which at least one of the plurality of mesa sidewalls contacts a protection liner 124 and contacts a shallow trench isolation 130.

Optionally, the semiconductor structure also includes a length of the at least one of the mesa sidewalls contacting the shallow trench isolation 130 is equal to or less than 50 nm.

Optionally, the semiconductor structure further includes a frontside contact 150 contacting the mesa top surface, and a backside contact 160 contacting the mesa bottom surface.

Optionally, the semiconductor structure further includes a backside power distribution network 162 connected to the backside contact 160.

In still a further aspect, an exemplary method of forming a semiconductor structure includes providing a semiconductor substrate 101, forming a multilayer stack of channel material 102 and sacrificial material 104, removing the multilayer stack from a passive region 120 of the substrate 101, growing a semiconductor 105 in the passive region, doping the semiconductor to form a top passive region 121 having a first polarity and lower passive region 122 having a second polarity wherein the first polarity is opposite of the second polarity, etching the multilayer stack and the semiconductor to form a multilayer stack fin and a semiconductor mesa 220 wherein the semiconductor mesa has a top mesa surface and a bottom mesa surface, forming a protection liner 124 on the semiconductor mesa, and forming a transistor region from the multilayer stack fin wherein the transistor region 110 comprises a top transistor 140 over a bottom transistor 240 wherein the top transistor includes a topmost channel 102T and the bottom transistor includes a bottommost channel 102B in which the top mesa surface is co-planar or above the topmost channel and the bottom mesa surface is co-planar or below the bottommost channel.

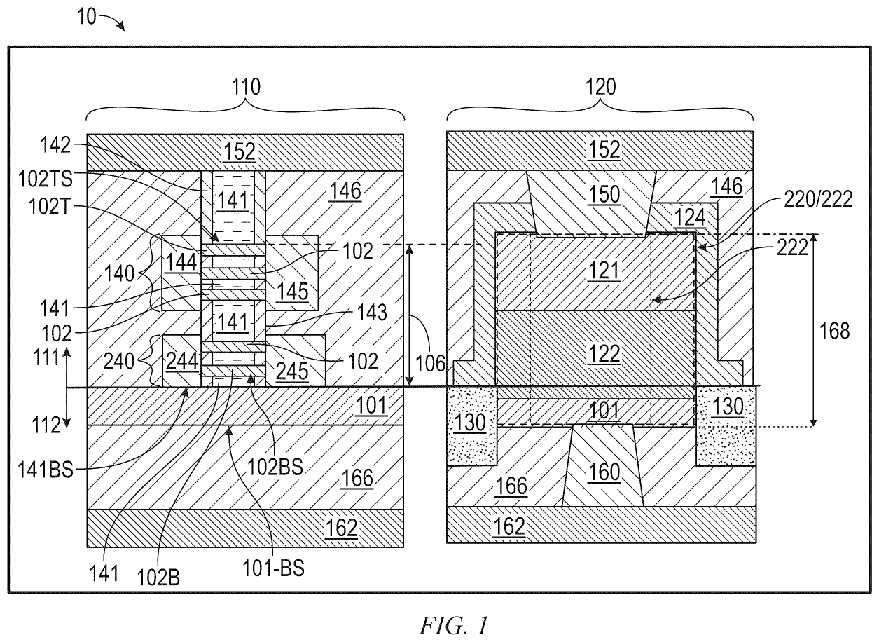

Aspects of invention provide techniques for a passive device having a backside contact integrated with a stack capital FET. FIG. 1 shows a semiconductor structure 10 having a transistor region 110 and a passive region 120. The two regions share a common substrate 101 which is a semiconductor substrate. The transistor region 110 may be a stacked logic transistor including a top transistor 140 can you find transistor 240. Each transistor has a source/drain pair (here, first source/drain 144, second source/drain 145 and third source/drain 244, fourth source/drain 245) connected by channel material 102. The channel material 102 is surrounded by a gate structure 141. The gate structure 141 has gate spacers 142 an inner spacers 143. The top transistor 140 has a topmost channel 102T which has a top surface 102TS. Similarly, the bottom transistor 240 has a bottommost channel 102B having a bottom surface 102BS. The portion of the gate structure 141 to load the bottommost channel 102B also has a gate structure bottom surface 141BS. The stacked FET of the transistor region 110 can be surrounded by a front side dielectric 146. Above the frontside dielectric 146 is the back end of line 152 interconnect layers. The previously described features are on the frontside 111 having this structure. Turning to the backside 112 of the structure, below a substrate 101 is the backside dielectric 166. Below backside dielectric 166 is a power distribution network 162 which may include power rails or other devices.

On the same substrate 101 of the semiconductor structure 10 is a passive region 120. The passive region 120 includes a semiconductor mesa 220 which includes a passive device 222. The passive device can be a diode. The passive device 222 is in a semiconductor mesa 220. As indicated by FIG. 1 labeling and dashed and dotted boxes, the passive device 222 may have the same footprint as the mesa 220, or as indicated by the inner dotted box, may have a narrower footprint compared to the semiconductor mesa 220. In either configuration, the passive device 222 has a front side contact 150 at a top surface and a backside contact at a bottom surface. The passive device 222 has a top class of region 121 and the bottom passive region 122. The two regions have opposite polarity from each other. Portions of the substrate 101 included in the passive device 222 are doped to lower contact resistance or otherwise integrate with the passive device 222. In some embodiments, the substrate 101 is not present.

Continuing with FIG. 1 the semiconductor mesa 220 has a bottom surface in contact with the backside dielectric 166 and the backside contact 160, sidewalls of the semiconductor mesa 220 are in contact with a shallow trench isolation 130 and protection liner 124. The top surface is in contact with protection liner 124 and front side contact 150. The protection liner 124 is a dielectric and can be a relatively thick oxide, for example, 5 to 10 nm or can be a nitride such as SiN. The frontside contact connects with the back end of line 152 interconnects. Frontside contact 150 can be surrounded by frontside dielectric 146. In the border line of the frontside 111 and the backside 112 of the semiconductor structure 10 is defined by the protective liner 124 and shallow trench isolation 130 interface.

With reference to FIG. 1 comparisons of heights and sizes of features in the transistor region 110 and passive region 120 are made. If viewed from top down, the semiconductor mesa 220 can be any shape, rectangle, oval, round, etc. In contrast, the semiconductor portions of a stacked transistor (i.e. source/drain, channels) are a line (or fin, if viewed in three-dimensions). The semiconductor mesa height 168 (which is the same as the passive device 222 height) can be measured from the top surface to the bottom surface of the semiconductor mesa 220 and can be from about 100 to 160 nm. In contrast the height of the stacked FET height 106 when measured from gate structure bottom surface 141BS to top surface 102TS of the topmost channel 102T is about 100 nm. The top of the semiconductor mesa 220/passive device 222 can be co-planar with or above the top surface 102TS of the topmost channel 102T. In contrast, the bottom of the semiconductor mesa 220/passive device 222 is below the bottom surface 102BS of the bottommost channel 102B.

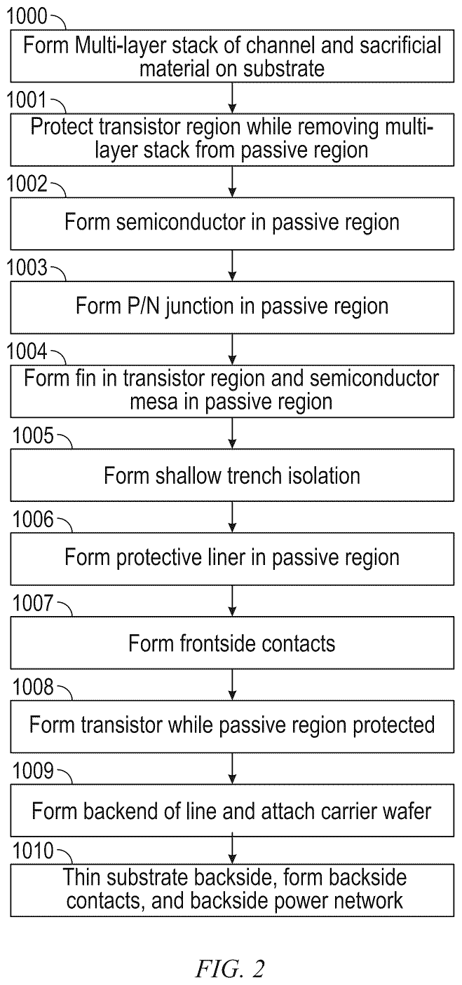

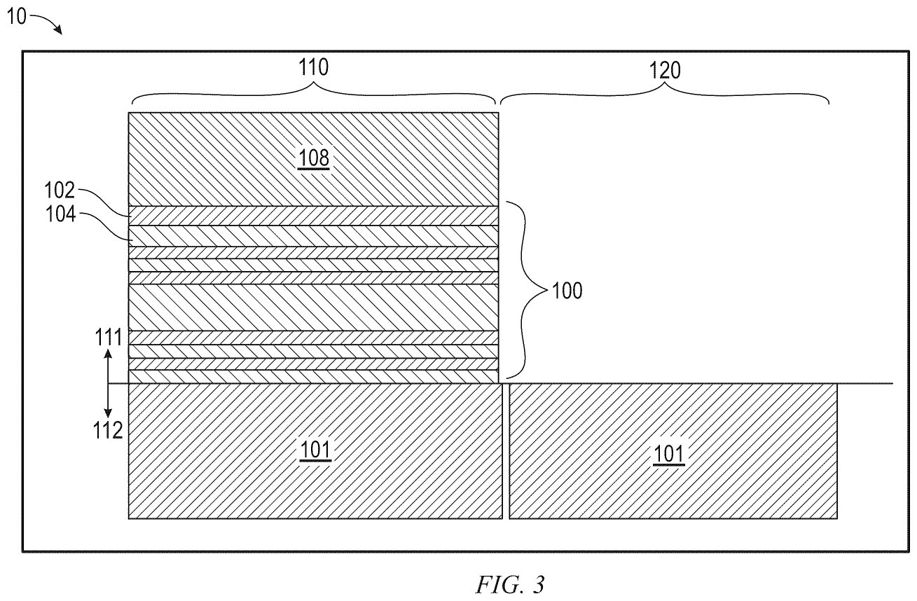

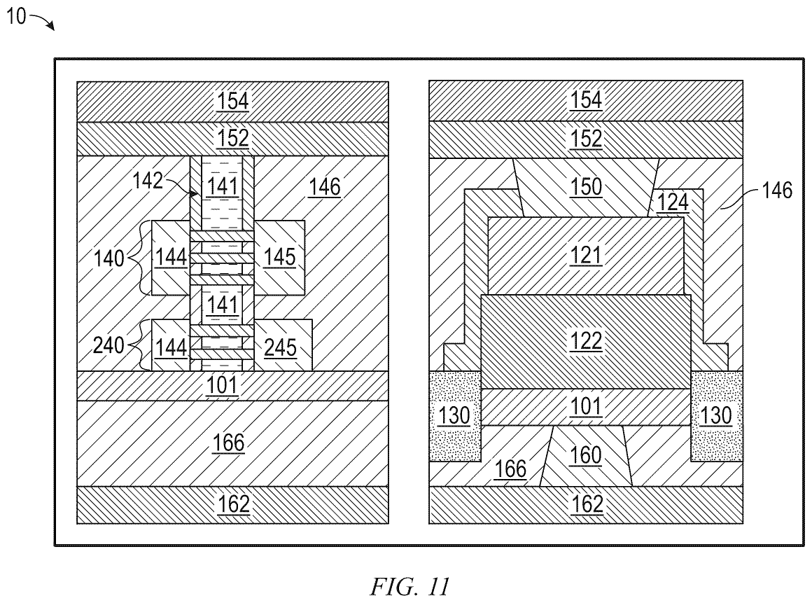

Referring now to FIG. 2 which lists steps of an exemplary process flow process steps to manufacture the structure of FIG. 1 in accordance with an aspect of the invention. Accompanying FIG. 2 are FIGS. 3-11 which depict cross-sections of a semiconductor structure 10 having a transistor region 110 and a passive region 120 during various steps of FIG. 2 in accordance with an aspect of the invention. In step 1000 a multi-layer stack 100 of channel material 102 and sacrificial material 104 is formed on a substrate 101.

In step 1001, the transistor region 110 is covered by hard mask 108 well the multilayer stack 100 is removed to expose the substrate 101 in the passive region 120 as seen in FIG. 3.

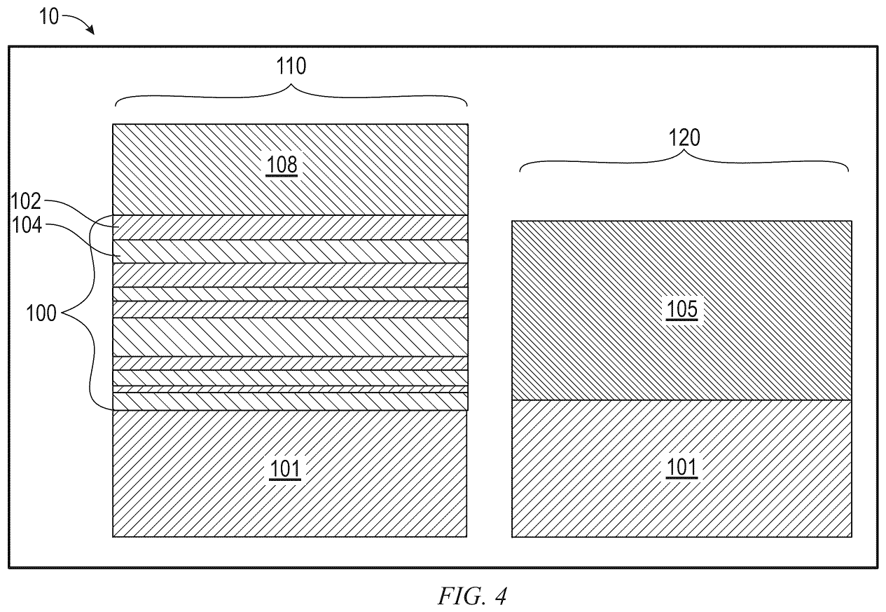

In step 1002 a semiconductor 105 is regrown over the substrate 101 in the passive region 120 as seen in FIG. 4. The semiconductor 105 can be grown to a height equal to the multi-layer stack 100.

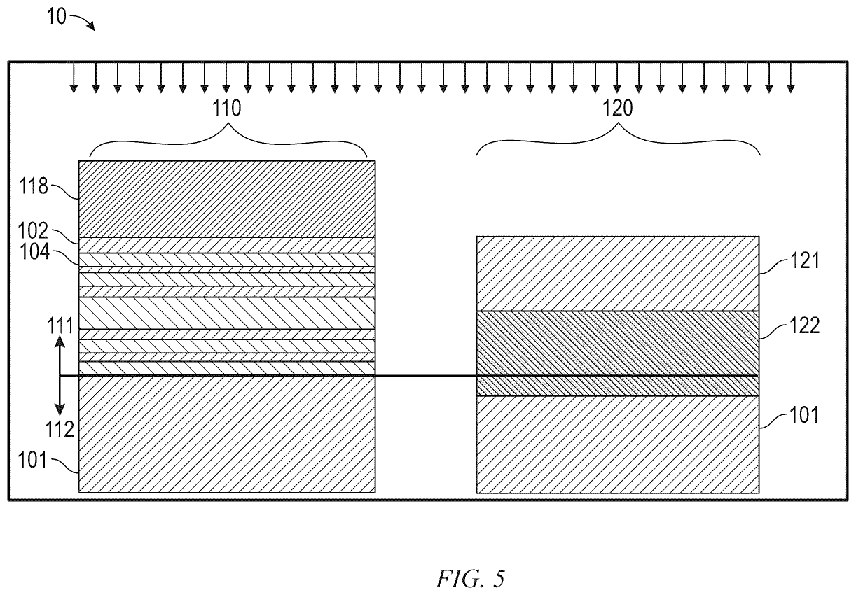

In step 1003, P/N junctions are formed in the passive region 120. Referring to FIG. 5, the transistor region 110 is shielded by layer 118 while the exposed passive region 120 is doped (e.g. at least in part by ion implantation) to form a top passive region 121 and a bottom passive region 122 resulting in each region being oppositely doped from the other. It is possible for the bottom passive region 122 doping to extend to the backside 112 of the semiconductor structure 10. Also note that in some embodiments, the layer 118 may cover a portion of the passive device region 120. In such instances, the resulting a top passive region 121 and a bottom passive region 122 of the passive device 222 will be narrower than the semiconductor mesa 220 (see the dotted box of embodiment of FIG. 1).

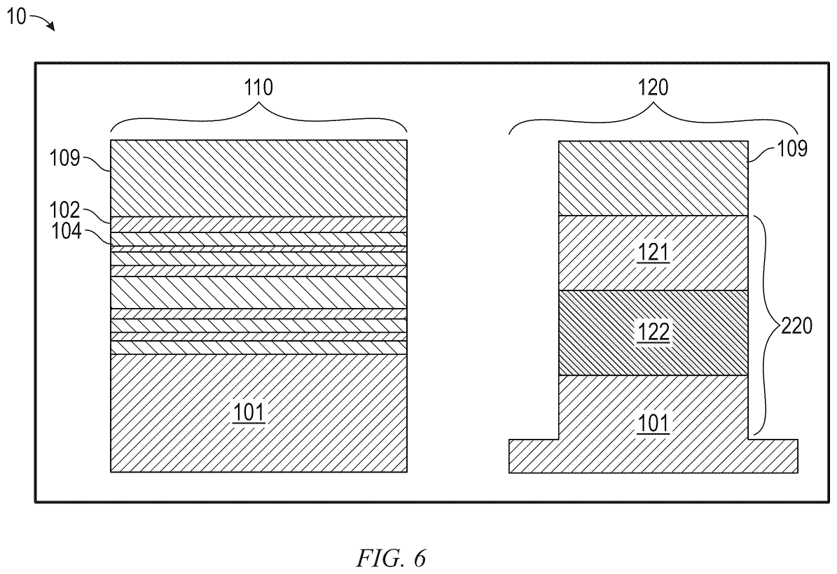

In step 1004, the semiconductor structure 10 is patterned to form a fin pattern in the transistor region 110 and a semiconductor mesa pattern in the passive region 120, also see FIG. 6 with a hardmask 109 over the multi-layer stack 100 to leave a fin pattern and over a portion of the top passive region 121. The patterning process results in removing some of the substrate 101 on either side of the hardmask 109 in the passivation region 120 leaving a semiconductor mesa 220.

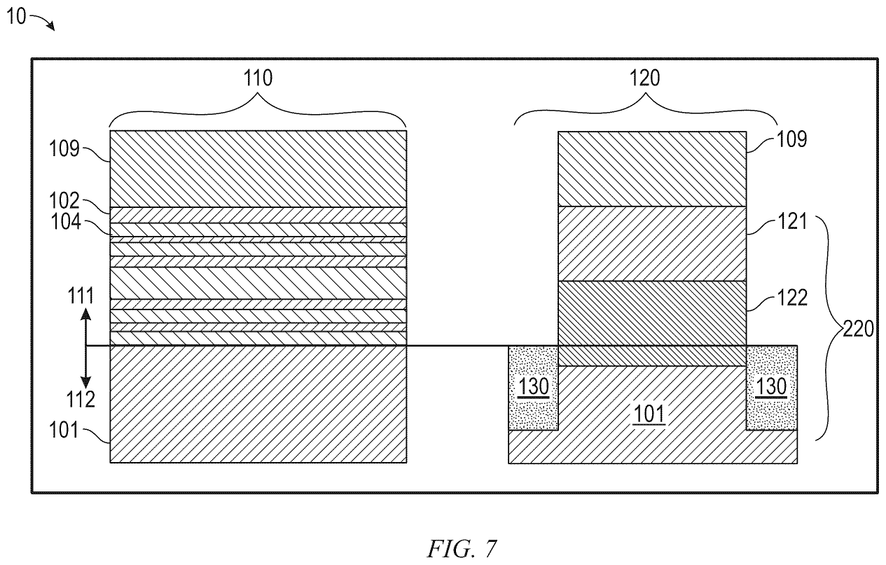

In step 1005, shallow trench isolation 130 is formed on either side of the semiconductor mesa 220, see FIG. 7.

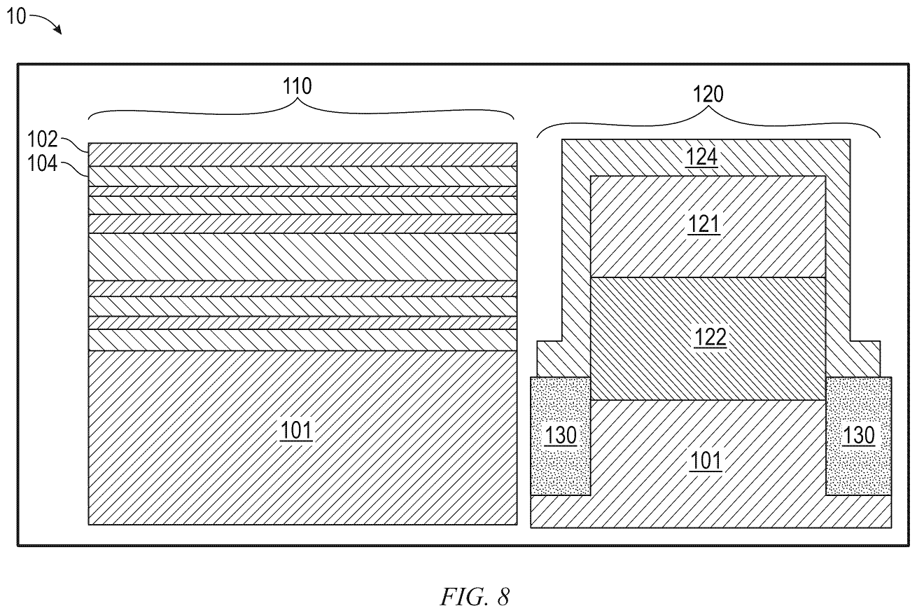

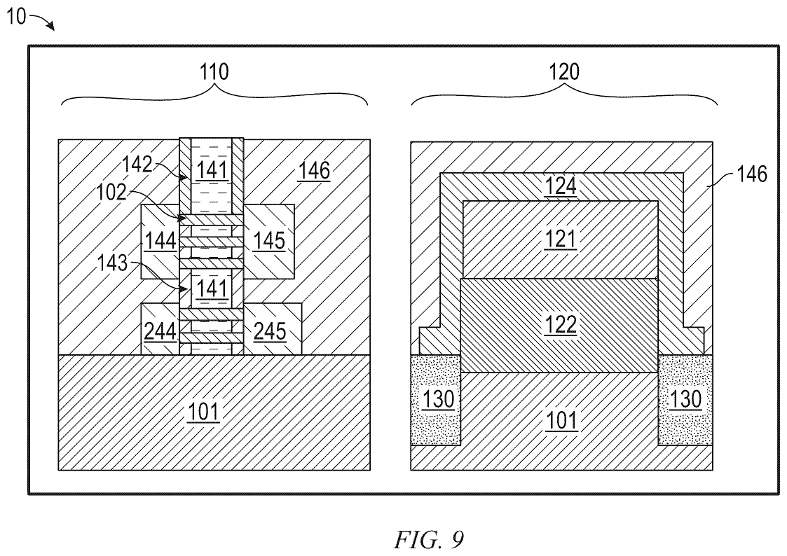

In step 1006, protective liner 124 is formed on either side of the semiconductor mesa 220, see FIG. 8. The protective liner 124 shields the semiconductor mesa 220 from the processes of the following step 1007, forming the stacked FET in the transistor region 110 (see FIG. 9).

After forming the stacked FET, in step 1008 frontside contacts 150 are formed. While FIG. 9 only shows a frontside contact 150 to the semiconductor mesa 220/passive device 222, contacts through frontside dielectric 146 may be made to the gate structure 141 or the source/drains.

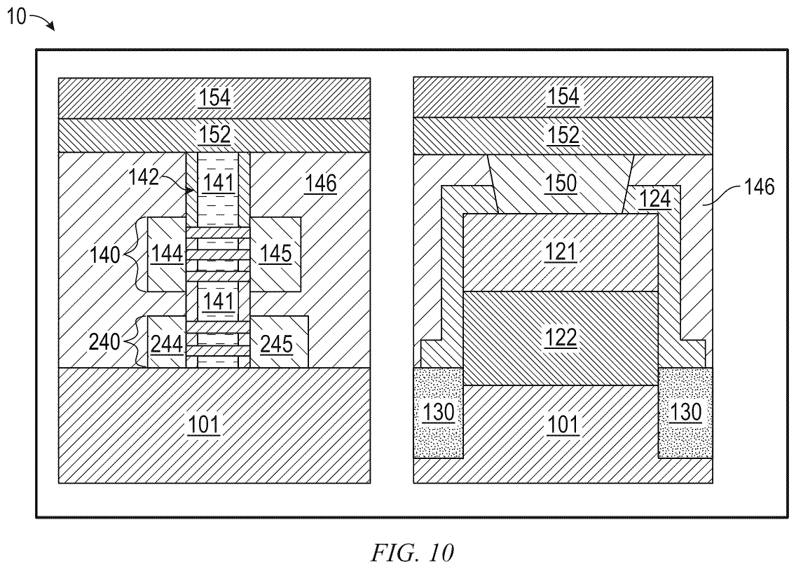

In step 1009, the rest of the frontside 111 processing is completed including forming back end of line 152 interconnect levels and preparing for backside 112 processing by attaching a carrier wafer 154 (see FIG. 10).

In step 1010, the backside 112 processing takes place. First, the substrate 101 is thinned. The final thickness of the substrate 101 can be from 0 nm (i.e. completely removed) to about 50 nm. A backside dielectric 166 is formed over the backside 112 and backside contact 160 is made to a bottom surface of the semiconductor mesa 220/passive device 222. In cases where the substrate 101 remains, the bottom surface of the semiconductor mesa 220/passive device 222 will be the remaining portion of the substrate 101. In cases in which the substrate 101 is completely removed, the bottom surface of the semiconductor mesa 220/passive device 222 will be the bottom passive region 122. While not pictured, it should be noted backside contacts can also be formed through the backside dielectric 166 to the stacked FET source/drain(s). Finally, a backside power distribution network 162, which may include a backside power rail, is formed in the backside 112 of the semiconductor structure 10.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure 10. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure 10. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a stacked transistor having a top transistor over a bottom transistor and a gate structure; and
a passive device positioned laterally to the stacked transistor and having a passive device top surface and a passive device bottom surface;
wherein:
the top transistor comprises a first source-drain connected to a second source drain by a topmost channel;
the bottom transistor comprises a third source-drain connected to a fourth source drain by a bottommost channel;
the gate structure surrounds the topmost channel and the bottommost channel;
the passive device top surface is no lower than a top surface of the topmost channel; and
the passive device bottom surface is no higher than a gate structure bottom surface.

2. The semiconductor structure of claim 1, wherein a passive device height is greater than a height from the gate structure bottom surface to the top surface of the top channel.

3. The semiconductor structure of claim 2, wherein a passive device height is from 100 nm to 160 nm.

4. The semiconductor structure of claim 2, wherein the height from the gate structure bottom surface to the top surface of the topmost channel is from 50 nm to 110 nm.

5. The semiconductor structure of claim 2, wherein a ratio of the passive device height to the height from the gate structure bottom surface to the top surface of the topmost channel is equal to or greater than 1.4.

6. A semiconductor structure comprising:
a stacked transistor having a top transistor over a bottom transistor and a gate structure; and
a passive device positioned laterally to the stacked transistor and having a passive device top surface, a passive device bottom surface and a plurality of passive device sidewalls;
a protection liner on the passive device; and
a shallow trench isolation under the protection liner laterally surrounding the passive device;
wherein at least one of the passive device sidewalls contacts the protection liner and contacts the shallow trench isolation.

7. The semiconductor structure of claim 6, wherein a length of the at least one of the passive device sidewalls contacting the shallow trench isolation is equal to or less than 50 nm.

8. The semiconductor structure of claim 6, further comprising:
a frontside contact contacting the passive device top surface; and
a backside contact contacting the passive device bottom surface.

9. A semiconductor structure comprising:
a logic region comprising vertically stacked top and bottom transistors wherein the top transistor includes a topmost channel and the bottom transistor includes a bottommost channel; and
a passive region comprising a semiconductor mesa having a top surface co-planar or above a topmost channel of the top transistor and a bottom surface no higher than the bottommost channel of the bottom transistor.

10. The semiconductor structure of claim 9, wherein the semiconductor mesa includes a vertical diode.

11. The semiconductor structure of claim 9, further comprising a frontside contact and a backside contact each connected to the semiconductor mesa.

12. The semiconductor structure of claim 9 wherein the semiconductor mesa is round when viewed in plan view.

13. A semiconductor structure comprising:
a substrate having a substrate frontside and a substrate backside;
a transistor region on the substrate frontside comprising:
a vertically stacked field effect transistor including a top transistor over a bottom transistor, wherein the top transistor includes a topmost channel and the bottom transistor includes a bottommost channel; and
a gate structure surrounding the topmost channel and the bottommost channel;
a passive region comprising a semiconductor mesa having a mesa top surface co-planar or above a top surface of the topmost channel and a mesa bottom surface no higher than a bottom surface of the bottommost channel; and
a backside contact contacting the mesa bottom surface.

14. The semiconductor structure of claim 13, wherein the semiconductor mesa includes a vertical diode.

15. The semiconductor structure of claim 13 wherein the semiconductor mesa is round when viewed in plan view.

16. The semiconductor structure of claim 13, wherein a semiconductor mesa height is greater than a height from the substrate backside to the top surface of the topmost channel.

17. The semiconductor structure of claim 13, wherein a semiconductor mesa height is greater than a height from a gate structure bottom surface to the top surface of the topmost channel.

18. The semiconductor structure of claim 17, wherein the semiconductor mesa height is from 100 nm to 160 nm.

19. The semiconductor structure of claim 17, wherein the height from the gate structure bottom surface to the top surface of the topmost channel is from 50 nm to 110 nm.

20. The semiconductor structure of claim 17, wherein a ratio of the semiconductor mesa height to the height from the gate structure bottom surface to the top surface of the topmost channel is equal to or greater than 1.4.

21. The semiconductor structure of claim 13, further comprising a plurality of mesa sidewalls wherein at least one of the plurality of mesa sidewalls contacts a protection liner and contacts a shallow trench isolation.

22. The semiconductor structure of claim 21, wherein a length of the at least one of the semiconductor mesa sidewalls contacting the shallow trench isolation is equal to or less than 50 nm.

23. The semiconductor structure of claim 13, further comprising:
a frontside contact contacting the mesa top surface.

24. The semiconductor structure of claim 23, further comprising:
a backside power distribution network connected to the backside contact.

25. A method of forming a semiconductor structure, comprising:
providing a semiconductor substrate;
forming a multilayer stack of channel material and sacrificial material;
removing the multilayer stack from a passive region of the substrate;
growing a semiconductor in the passive region;
doping the semiconductor to form a top passive region having a first polarity and lower passive region having a second polarity wherein the first polarity is opposite of the second polarity;
etching the multilayer stack and the semiconductor to form a multilayer stack fin and a semiconductor mesa wherein the semiconductor mesa has a top mesa surface and a bottom mesa surface;
forming a protection liner on the semiconductor mesa; and
forming a transistor region from the multilayer stack fin wherein the transistor region comprises a top transistor over a bottom transistor wherein the top transistor includes a topmost channel and the bottom transistor includes a bottommost channel;
wherein the top mesa surface is no lower than the topmost channel and the bottom mesa surface is no higher than the bottommost channel.
